(19) United States
(12) Patent Application Publication
(10) Pub. No.: US 2024/0052516 A1
(43) Pub. Date: Feb. 15, 2024

(54) METAL PART FOR PROCESS CHAMBER AND METHOD OF FORMING THIN FILM LAYER OF METAL PART FOR PROCESS CHAMBER

(71) Applicant: POINT ENGINEERING CO., LTD., Asan (KR)

(72) Inventor: Bum Mo AHN, Suwon (KR)

(21) Appl. No.: 18/496,161

(22) Filed: Oct. 27, 2023

Related U.S. Application Data
(62) Division of application No. 17/070,057, filed on Oct. 14, 2020.

(30) Foreign Application Priority Data
Oct. 16, 2019 (KR) 10-2019-0128697

(51) Int. Cl. C25D 11/12; C25D 11/04; C23C 16/44

(52) U.S. Cl. CPC C25D 11/12; C25D 11/045; C23C 16/4404

(57) ABSTRACT

Proposed are a metal part for a process chamber and a method of forming a thin film layer of the metal part for the process chamber. More particularly, proposed are a metal part for a process chamber and a method of forming a thin film layer of the metal part for the process chamber, wherein the metal part is installed in a process chamber used in a display or semiconductor manufacturing process or constitutes a part of the process chamber, and a large thickness of the thin film layer of the metal part for the process chamber is easily secured, thereby achieving an extended lifespan by preventing cracks of the metal part for the process chamber, while preventing outgassing due to pores.

### CROSS REFERENCE TO RELATED APPLICATIONS

The present application is a division of U.S. patent application Ser. No. 17/070,057 filed on Oct. 14, 2020, which claims priority to Korean Patent Application No. 10-2019-0128697, filed Oct. 16, 2019, the entire contents of which are incorporated herein for all purposes by this reference.

### BACKGROUND OF THE INVENTION

### Field of the Invention

The present invention relates to a metal part for a process chamber and a method of forming a thin film layer of the metal part for the process chamber. More particularly, the present invention relates to a metal part for a process chamber, the metal part being installed in a process chamber used in a display or semiconductor manufacturing process or constituting a part of the process chamber, and to a method of forming a thin film layer of the metal part for the process chamber.

### Description of the Related Art

A chemical vapor deposition (CVD) apparatus, a physical vapor deposition (PVD) apparatus, a dry etching apparatus, etc. (hereinafter referred to as “process chamber”) allows the use of reactant gas, etching gas, or cleaning gas (hereinafter referred to as “process gas”) inside a process chamber.

As corrosive gas such as Cl, F, or Br is mainly used as the process gas, corrosion resistance to the corrosive gas becomes a very important factor.

There has been a conventional technique in which stainless steel is used for a metal part for a process chamber. However, stainless steel does not have sufficient thermal conductivity, and also, in some cases, heavy metals such as Cr and Ni, which are alloy components of stainless steel, are released during a process and become a source of contamination.

Therefore, a metal part for a process chamber that is made of pure aluminum or an aluminum alloy, which is lighter than stainless steel, has excellent thermal conductivity, and is free from causing heavy metal contamination, has been developed. However, a surface of the aluminum or aluminum alloy has poor corrosion resistance, and thus methods of surface treatment have been studied.

As an example of such surface treatment methods, a method of forming an anodic oxide film by performing anodization treatment on a surface of aluminum or an aluminum alloy has been studied.

The anodic oxide film is formed by first forming a non-porous bather layer with no pores, and then forming a porous layer with pores.

The non-porous bather layer of the anodic oxide film has a thickness of equal to or less than 1 μm, which is a very small thickness. The porous layer can be formed with a thickness ranging from several tens of μm to several hundreds of μm depending on the time for forming the anodic oxide film, and has a relatively larger thickness than the non-porous bather layer.

When the surface treatment of a metal part for a process chamber is such that both the non-porous bather layer and the porous layer are formed, there is an advantage of securing a certain thickness. However, a contradictory problem occurs due to the pores of the porous layer. In detail, foreign substances inside the process chamber enter the pores of the porous layer. In this case, when the process proceeds in the process chamber, foreign substances remaining in the pores escape and fall on a substrate surface, causing a problem in that particles are generated on the substrate. This phenomenon is referred to as outgassing of foreign substances, and is a major cause of process defects in the process chamber, a decrease in production yield, and shortening of a maintenance cycle of the process chamber.

In order to prevent such outgassing, when the surface treatment of the metal part for the process chamber is such that only the non-porous bather layer is formed, the very small thickness of the non-porous bather layer causes a problem in that the anodic oxide film cracks or peels off due to a change in internal stress or due to thermal expansion. In addition, the thin anodic oxide film composed of only the non-porous bather layer has a short lifespan, so that an aluminum or aluminum alloy base is easily exposed, and plasma arcing occurs in which plasma is concentrated at the exposed base part, causing a problem in that a base surface is partially melted or damaged.

As described above, in the case of forming a surface treatment layer (hereinafter referred to as “thin film layer”) of the metal part for the process chamber with only the conventional anodic oxide film, both securing the thickness of the surface treatment layer and preventing the occurrence of outgassing could not be solved.

Accordingly, there is a need to develop a metal part for a process chamber and a method of manufacturing the same, whereby a large thickness of a thin film layer of the metal part for the process chamber can be secured, while preventing outgassing.

The foregoing is intended merely to aid in the understanding of the background of the present invention, and is not intended to mean that the present invention falls within the purview of the related art that is already known to those skilled in the art.

### DOCUMENTS OF RELATED ART

(Patent document 1) Korean Patent No. 10-0482862
(Patent document 2) Korean Patent Application Publication No. 10-2011-0130750
(Patent document 3) Korean Patent Application Publication No. 10-2008-0000112

### SUMMARY OF THE INVENTION

Accordingly, the present invention has been made keeping in mind the above problems occurring in the related art, and an objective of the present invention is to provide a metal part for a process chamber and a method of forming a thin film layer of the metal part for the process chamber, wherein a large thickness of the thin film layer of the metal part for the process chamber is easily secured, thereby achieving an extended lifespan by preventing cracks of the metal part for the process chamber, while preventing outgas sing due to pores.

In order to achieve the above objective, according to one aspect of the present invention, there is provided a metal part for a process chamber, the metal part including: a first thin film layer composed of an anodic oxide film layer, the first thin film layer being formed on a top of a metal base by anodizing the metal base; and a second thin film layer composed of a plurality of first monoatomic layers, the second thin film layer being formed on a top of the first thin film layer by repeatedly performing a cycle of adsorbing a first-first precursor on the top of the first thin film layer and of supplying a first-second reactant of a different kind from the first-first precursor to form a first monoatomic layer through chemical substitution of the first-second reactant with the first-first precursor.

Furthermore, a thickness of the second thin film layer may be in a range of equal to or greater than 20 nm to equal to or less than 3 μm.

Furthermore, the metal part may further include: a third thin film layer composed of plurality of second monoatomic layers, the third thin film layer being formed on a top of the second thin film layer by repeatedly performing a cycle of adsorbing a second-first precursor on the top of the second thin film layer and of supplying a second-second reactant of a different kind from the second-first precursor to form a second monoatomic layer through chemical substitution of the second-second reactant with the second-first precursor, wherein the second thin film layer and the third thin film layer may have different components.

Furthermore, the anodic oxide film layer may be located on the top of the metal base and may be composed of a non-porous bather layer having no pores formed therein, wherein a thickness of the non-porous bather layer may be in a range of equal to or greater than 100 nm to equal to or less than 1 μm.

Furthermore, the anodic oxide film layer may be located on the top of the metal base and may be composed of a non-porous bather layer having no pores formed therein and a porous layer located on a top of the non-porous bather layer and having pores formed therein, wherein parts of the second thin film layer may be located inside the pores of the porous layer.

Furthermore, the metal part may be a metal part that is installed inside a process chamber in which chemical vapor deposition is performed, and may be at least one of a diffuser, a backing plate, a shadow frame, a susceptor, a guard ring, and a slit valve.

Furthermore, the metal part may be a metal part that is installed inside a process chamber in which dry etching is performed, and may be at least one of a bottom electrode, an electrostatic chuck of the bottom electrode, a baffle of the bottom electrode, an upper electrode, a wall liner, a guard ring, and a slit valve.

According to another aspect of the present invention, there is provided a method of forming a thin film layer of a metal part for a process chamber, the method including: anodizing a metal base to form a first thin film layer composed of an anodic oxide film layer on a top of the metal base; adsorbing a first-first precursor on a top of the first thin film layer; supplying a first-second reactant of a different kind from the first-first precursor to form a first monoatomic layer through chemical substitution of the first-second reactant with the first-first precursor; and repeatedly performing a cycle of forming the first monoatomic layer to form a second thin film layer composed of a plurality of first monoatomic layers on the top of the first thin film layer.

Furthermore, the cycle may be repeatedly performed until a thickness of the second thin film layer becomes in a range of equal to or greater than 20 nm to equal to or less than 3 μm.

Furthermore, the method may further include: forming a third thin film layer composed of a plurality of second monoatomic layers on the top of the second thin film layer by adsorbing a second-first precursor on a top of the second thin film layer, by supplying a second-second reactant of a different kind from the second-first precursor to form a second monoatomic layer through chemical substitution of the second-second reactant with the second-first precursor, and by repeatedly performing a cycle of forming the second monoatomic layer, wherein the second thin film layer and the third thin film layer may have different components.

According to the metal part for the process chamber and the method of forming the thin film layer of the metal part for the process chamber according to the present invention as described above, the following effects are provided.

By forming the first thin film layer composed of the anodic oxide film layer on the top of the metal base, even if the second thin film layer and/or the third thin film layer is removed, it is possible to prevent a foreign substance of the metal base from being easily eluted.

By forming the first thin film layer composed of the anodic oxide film layer on the top of the metal base and forming the second thin film layer composed of the plurality of first monoatomic layers on the top of the first thin film layer, it is possible to secure a sufficient thickness of the thin film layer.

By forming the second thin film layer composed of the plurality of first monoatomic layers, it is possible to entirely fill the pores of the porous layer, thereby effectively preventing outgassing.

By configuring the second thin film layer and the third thin film layer to have different components, it is possible to manufacture the metal part for the process chamber that has various properties.

### BRIEF DESCRIPTION OF THE DRAWINGS

The above and other objectives, features, and other advantages of the present invention will be more clearly understood from the following detailed description when taken in conjunction with the accompanying drawings, in which:

FIG. 1 is a view illustrating a metal part for a process chamber according to an exemplary embodiment of the present invention;

FIGS. 2A to 2E are views illustrating a process of forming a first thin film layer and a second thin film layer of the metal part for the process chamber illustrated in FIG. 1;

FIG. 3 is a schematic view illustrating a method of forming a thin film layer of the metal part for the process chamber according to the exemplary embodiment of the present invention;

FIGS. 4A to 4C are views illustrating a process of forming a thin film layer on a porous layer of a metal part for a process chamber according to the related art;

FIGS. 5A to 5C are views illustrating a process of forming a second thin film layer on a porous layer of the metal part for the process chamber according to the exemplary embodiment of the present invention;

FIG. 6 is a view illustrating a metal part for a process chamber according to a modified example of the present invention;

FIG. 7 is a view illustrating a process chamber for chemical vapor deposition in which chemical vapor deposition is performed, in which the metal part according to the exemplary embodiment of the present invention constitutes an inner surface of the process chamber or is installed as a metal part; and

FIG. 8 is a view illustrating a process chamber for dry etching in which dry etching is performed, in which the metal part according to the exemplary embodiment of the present invention constitutes an inner surface of the process chamber or is installed as a metal part.

### DETAILED DESCRIPTION OF THE INVENTION

Hereinafter, exemplary embodiments of the present invention will be described in detail with reference to the accompanying drawings. The advantages and features of the present invention and methods of achieving them will be apparent from the following exemplary embodiments that will be described in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Throughout the specification, the same reference numerals will refer to the same or like parts.

Terms used in the specification are for the purpose of describing the embodiments but is not intended to limit the scope of the present invention. As used herein, the singular forms are intended to include the plural forms as well, unless the context clearly indicates otherwise. It will be further understood that the terms “comprise” and/or “comprising” used herein specify the presence of stated components, steps, operations, and/or elements but do not preclude the presence or addition of one or more other components, steps, operations, and/or elements.

Also, reference numerals presented according to an order of description are not limited to the order.

The embodiments of the present invention will be described with reference to cross-sectional views and/or perspective views which schematically illustrate ideal embodiments of the present invention. In the drawings, thicknesses of films and regions are exaggerated for effective description of technical contents. Therefore, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. Thus, the exemplified regions illustrated in the drawings are schematic in nature, and their shapes are not intended to illustrate the specified shape of a region of a device and are not intended to limit the scope of the present invention.

Wherever possible, the same reference numerals will be used throughout different embodiments and the description to refer to the same or like elements or parts. In addition, the configuration and operation already described in other embodiments will be omitted for convenience.

Hereinafter, a metal part 1 for a process chamber according to an exemplary embodiment of the present invention will be described.

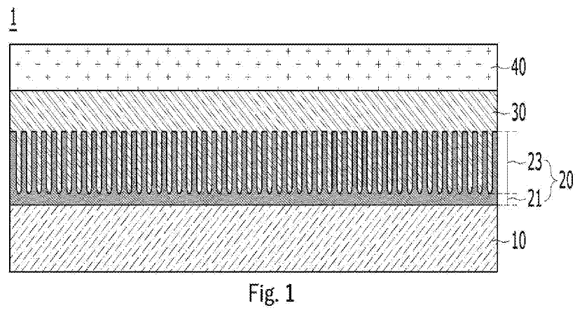

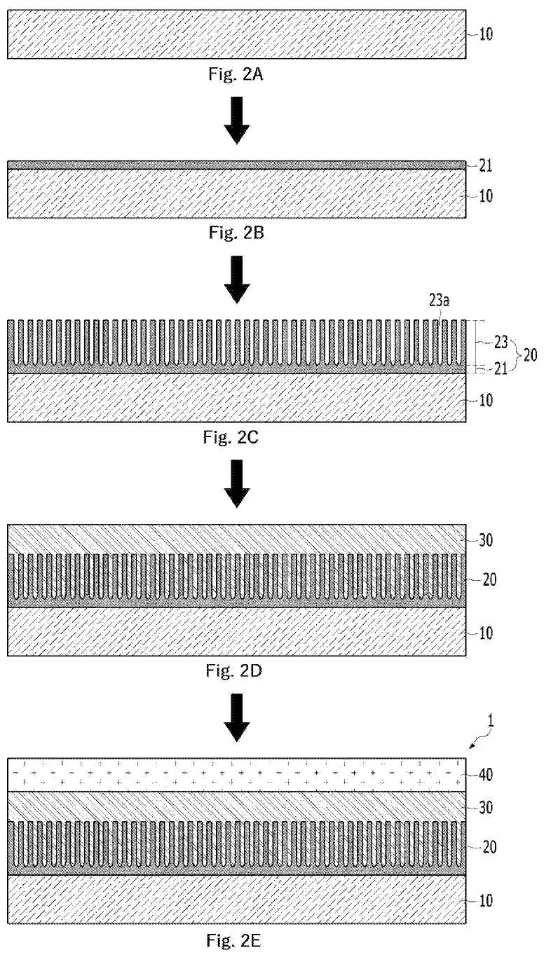

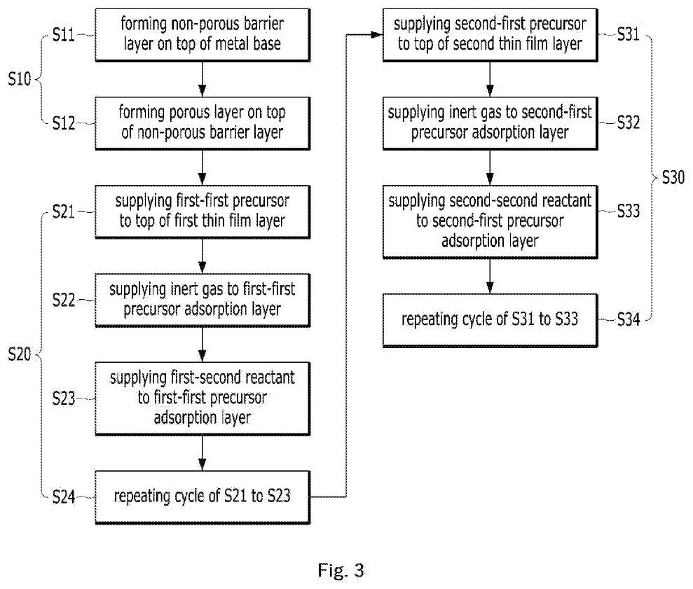

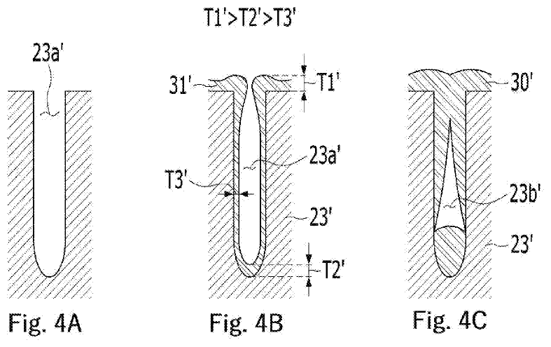

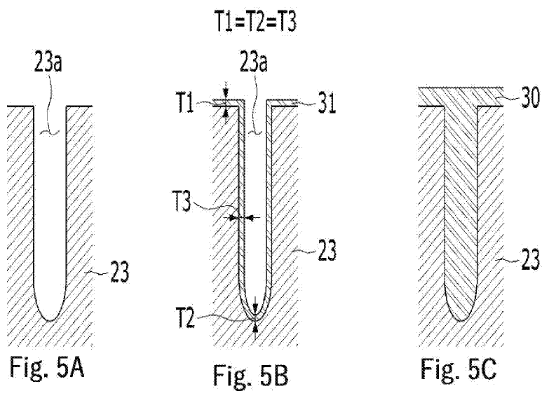

FIG. 1 is a view illustrating a metal part for a process chamber according to an exemplary embodiment of the present invention, FIGS. 2A to 2E are views illustrating a process of forming a first thin film layer and a second thin film layer of the metal part for the process chamber illustrated in FIG. 1, FIG. 3 is a schematic view illustrating a method of forming a thin film layer of the metal part for the process chamber according to the exemplary embodiment of the present invention, FIGS. 4A to 4C are views illustrating a process of forming a thin film layer on a porous layer of a metal part for a process chamber according to the related art, and FIGS. 5A to 5C are views illustrating a process of forming a second thin film layer on a porous layer of the metal part for the process chamber according to the exemplary embodiment of the present invention;

As illustrated FIG. 1 and FIGS. 2A and 2B, the metal part 1 for the process chamber according to the exemplary embodiment of the present invention may be configured such that a first thin film layer 20 is formed by anodizing a metal base 10, and then a second thin film layer 30 is formed on a top of the first thin film layer 20, thereby more effectively securing the thickness of a thin film layer.

In addition, the thin film layer may include: the second thin film layer 30 formed on the top of the first thin film layer 20, and composed of a plurality of first monoatomic layers 31 that are formed by repeatedly performing a cycle of adsorbing a first-first precursor on the top of the first thin film layer 20 and of supplying a first-second reactant of a different kind from the first-first precursor to form a first monoatomic layer 31 through chemical substitution of the first-second reactant with the first-first precursor; and a third thin film layer 40 formed on a top of the second thin film layer 30, and composed of a plurality of second monoatomic layers that are formed by repeatedly performing a cycle of adsorbing a second-first precursor on the top of the second thin film layer 30 and of supplying a second-second reactant of a different kind from the second-first precursor to form a second monoatomic layer through chemical substitution of the second-second reactant with the second-first precursor.

In other words, the metal part 1 for the process chamber according to the exemplary embodiment of the present invention is configured such that the first thin film layer 20 composed of an anodic oxide film layer is formed on a top of the metal base 10 by anodizing the metal base 10, the second thin film layer 30 composed of the plurality of first monoatomic layers 31 is formed on the top of the first thin film layer 20 by repeatedly performing the cycle of adsorbing the first-first precursor on the top of the first thin film layer 20 and of supplying the first-second reactant of the different kind from the first-first precursor to form the first monoatomic layer 31 through chemical substitution of the first-second reactant with the first-first precursor, and the third thin film layer 40 composed of the plurality of second monoatomic layers is formed on the top of the second thin film layer 30 by repeatedly performing the cycle of adsorbing the second-first precursor on the top of the second thin film layer 30 and of supplying the second-second reactant of the different kind from the second-first precursor to form the second monoatomic layer through chemical substitution of the second-second reactant with the second-first precursor.

The metal base 10 may be made of a metal material selected from one of aluminum (Al), titanium (Ti), tungsten (W), zinc (Zn), etc., but preferably aluminum or an aluminum alloy, which is lightweight, easy to process, excellent in thermal conductivity, and free from causing heavy metal contamination.

The first thin film layer 20 is formed on the top of the metal base 10 by anodizing the metal base 10 to form an anodic oxide film layer on the top of the metal base 10.

In this case, the first thin film layer 20, i.e., the anodic oxide film layer, is located on the top of the metal base 10, i.e., on a surface of the metal base 10, and may include a non-porous bather layer 21 having no pores 23a formed therein, and a porous layer 23 located on a top of the non-porous bather layer 21, i.e., on a surface of the non-porous bather layer 21, and having pores 23a formed therein.

When the metal base 10 is anodized, the non-porous barrier layer 21 is first generated, and when the non-porous bather layer 21 is formed to a predetermined thickness, the porous layer 23 is formed.

The thickness of the non-porous bather layer 21 is preferably several hundreds of nm, more preferably in the range of equal to or greater than 100 nm to equal to or less than 1 μm.

The thickness of the porous layer 23 is in the range of several tens of μm to several hundreds of μm.

If the metal base 10 is aluminum or an aluminum alloy, the first thin film layer 20 is an anodic oxide film layer formed by anodizing the metal base 10 made of the aluminum or aluminum alloy, and such an anodic oxide film layer, i.e., the first thin film layer 20 is composed of aluminum oxide (Al₂O₃).

The anodic oxide film layer of the first thin film layer 20 has an amorphous property.

The second thin film layer 30 is formed on the top of the first thin film layer 20, i.e., on a surface of the first thin film layer 20, and is composed of the plurality of first monoatomic layers 31.

The second thin film layer 30 may be formed by repeatedly performing the cycle of adsorbing the first-first precursor on the top of the first thin film layer 20, i.e., the surface of the first thin film layer 20, and of supplying the first-second reactant of the different kind from the first-first precursor to form the first monoatomic layer 31 through chemical substitution of the first-second reactant with the first-first precursor.

Examples of components of the plurality of first monoatomic layers 31, i.e., the second thin film layer 30, may include at least one of aluminum oxide (Al₂O₃), yttrium oxide (Y₂O₃), aluminum nitride (AlN), silicon dioxide (SiO₂), and silicon nitride (Si₃N₄), and silicon carbide (SiC).

The thickness of the second thin film layer 30 is preferably in the range of equal to or greater than 20 nm to equal to or less than 3 μm.

Parts of the second thin film layer 30, i.e., parts of a lower portion of the second thin film layer 30, are located inside the pores 23a of the porous layer 22 of the first thin film layer 20.

The first monoatomic layers 31 of the second thin film layer 30 have a crystalline property.

The third thin film layer 40 is formed on the top of the second thin film layer 30, i.e., on a surface of the second thin film layer 30, and is composed of the plurality of second monoatomic layers.

The third thin film layer 40 is formed by repeatedly performing the cycle of adsorbing the second-first precursor on the top of the second thin film layer 30, i.e., the surface of the second thin film layer 30, and of supplying the second-second reactant of the different kind from the second-first precursor to form the second monoatomic layer through chemical substitution of the second-second reactant with the second-first precursor.

Examples of components of the plurality of second monoatomic layers, i.e., the third thin film layer 40, may include at least one of aluminum oxide (Al₂O₃), yttrium oxide (Y₂O₃), aluminum nitride (AlN), silicon dioxide (SiO₂), and silicon nitride (Si₃N₄), and silicon carbide (SiC).

Each of the second monoatomic layers, i.e., the third thin film layer 40, has a component different from that of each of the first monoatomic layers 31, i.e., the second thin film layer 30.

For example, when the component of each of the second monoatomic layers, i.e., the third thin film layer 40, is aluminum oxide (Al₂O₃), the component of each of the first monoatomic layers 31, i.e., the second thin film layer 30, is silicon dioxide (SiO₂).

The thickness of the third thin film layer 40 is preferably in the range of equal to or greater than 20 nm to equal to or less than 3 μm.

The second monoatomic layers of the third thin film layer 40 have a crystalline property. Hereinafter, a method of forming a thin film layer of a metal part for a process chamber having the above-described configuration will be described in detail with reference to FIGS. 1 to 3. The method of forming the thin film layer of the metal part for the process chamber may include, as illustrated in FIG. 3, a first thin film layer forming step S10 of anodizing a metal base to form a first thin film layer 20 composed of an anodic oxide film layer on a top of the metal base 10, a second thin film layer forming step S20 of forming a second thin film layer 30 composed of a plurality of first monoatomic layers 31 on a top of the first thin film layer 20, and a third thin film layer forming step S30 of forming a third thin film layer 40 composed of a plurality of second monoatomic layers on a top of the second thin film layer 30 and having a component different from that of the third thin film layer 40.

In other words, the method of forming the metal part for the process chamber is performed in such a manner that: the metal base 10 is anodized to form the first thin film layer 20 composed of the anodic oxide film layer on the top of the metal base 10; a first-first precursor is adsorbed on the top of the first thin film layer 20; a first-second reactant of a different kind from the first-first precursor is supplied to form a first monoatomic layer 31 through chemical substitution of the first-second reactant with the first-first precursor; a cycle of forming the first monoatomic layer 31 is repeatedly performed to form the second thin film layer 30 composed of the plurality of first monoatomic layers 31; a second-first precursor is adsorbed on the second thin film layer 30; a second-second reactant of a different kind from the second-first precursor is supplied to form a second monoatomic layer through chemical substitution of the second-second reactant with the second-first precursor; and a cycle of forming the second monoatomic layer is repeatedly performed to form the third thin film layer 40 composed of the plurality of second monoatomic layers on the top of the second thin film layer 30.

In the first thin film layer forming step S10, a process in which an anodic oxide film layer is formed by anodizing the metal base 10 is performed.

The first thin film layer forming step S10 may include a non-porous bather layer forming step S11 and a porous layer forming step S12.

In the non-porous bather layer forming step S11, a process in which the metal base 10 is anodized to grow the non-porous bather layer 21 on a surface of the metal base 10, i.e., on the top of the metal base 10, thereby forming the non-porous bather layer 21 is performed. In this case, no pores 23a are formed inside the non-porous bather layer 21.

The non-porous bather layer forming step S11 is performed until the non-porous bather layer 21 is grown to a predetermined thickness, and the thickness of the non-porous bather layer 21 is preferably in the range of equal to or greater than 100 nm to equal to or less than 1 μm.

After the non-porous bather layer forming step S11 is completed, the porous layer forming step S12 is performed.

In the porous layer forming step S12, a process in which the porous layer 23 is grown on a top of the non-porous bather layer 21, i.e., on a surface of the non-porous bather layer 21, to form the porous layer 23 is performed. In this case, a pore 23a is formed inside the porous layer 23.

A plurality of pores 23a of the porous layer 23 is formed. The plurality of pores 23a are arranged at uniform intervals, and are configured to have uniform diameters.

The porous layer forming step S12 is performed until the porous layer 23 is grown to a predetermined thickness, and the thickness of the porous layer 23 is preferably in the range of several tens of μm to several hundreds of μm.

After the first thin film layer forming step S10 is completed through the above-described non-porous bather layer forming step S11 and the porous layer forming step S12, the second thin film layer forming step S20 is performed.

In the second thin film layer forming step S20, a process in which the cycle of forming the first monoatomic layer 31 is repeatedly performed to form the second thin film layer 30 composed of the plurality of first monoatomic layers 31 is performed.

The second thin film layer forming step S20 is performed such that parts of a lower portion of the second thin film layer 30 are located inside the pores 23a of the porous layer 23. The second thin film layer forming step S20 may include a first-first precursor adsorption step S21, a first inert gas supply step S22, a first-second reactant adsorption and substitution step S23, and a first cycle repetition step S24.

In the first-first precursor adsorption step S21, a process in which the first-first precursor is supplied to the top of the first thin film layer 20 composed of an anodic oxide film layer, i.e., to a surface of the first thin film layer 20, to adsorb the first-first precursor on the top of the first thin film layer 20, i.e., on the surface of the first thin film layer 20, thereby forming a first-first precursor adsorption layer is performed. In this case, the first-first precursor adsorption layer is configured as only a single layer by a self-limiting reaction.

After the first-first precursor adsorption step S21 is completed, the first inert gas supply step S22 is performed.

In the first inert gas supply step S22, a process in which an inert gas is supplied to remove excess first-first precursor from the first-first precursor adsorption layer is performed. In this case, the inert gas removes the excess first-first precursor remaining in the first-first precursor adsorption layer configured as only a single layer by the self-limiting reaction.

After the first inert gas supply step S22 is completed, the first-second reactant adsorption and substitution step S23 is performed.

In the first-second reactant adsorption and substitution step S23, a process in which the first-second reactant is supplied to a top of the first-first precursor adsorption layer, i.e., to a surface of the first-first precursor adsorption layer, to adsorb the first-second reactant on the top of the first-first precursor adsorption layer, i.e., on the surface of the first-first precursor adsorption layer, thereby forming the first monoatomic layer 31 through chemical substitution of the first-first precursor adsorption layer with the first-second reactant is performed.

The first-second reactant and the first-first precursor have different components.

Since the first monoatomic layer 31 is formed through chemical substitution of the first-first precursor adsorption layer composed of the first-first precursor with the first-second reactant, the first monoatomic layer 31 has a component different from those of the first-first precursor and the first-second reactant.

In the process of forming the first monoatomic layer 31 through chemical substitution, a remaining component among the components of the first-first precursor and the first-second reactant is discharged as gas.

After the first-second reactant adsorption and substitution step S23 is completed, the first cycle repetition step S24 is performed.

In the first cycle repetition step S24, a process in which a cycle of sequentially performing the first-first precursor adsorption step S21, the first inert gas supply step S22, and the first-second reactant adsorption and substitution step S23 is repeated to form the plurality of first monoatomic layers 31, thereby forming the second thin film layer 30 composed of the plurality of first monoatomic layers 31 is performed.

Through the first cycle repetition step S24, the second thin film layer 30 composed of the plurality of first monoatomic layers 31 may be formed to a predetermined thickness.

In other words, the first cycle repetition step S24 is performed until the second thin film layer 30 composed of the plurality of first monoatomic layers 31 is formed to a predetermined thickness, and the thickness of the second thin film layer 30 is preferably in the range of equal to or greater than 20 nm to equal to or less than 3 μm.

After the second thin film layer forming step S20 is completed through the first-first precursor adsorption step S21, the first inert gas supply step S22, the first-second reactant adsorption and substitution step S23, and the first cycle repetition step S24, the third thin film layer forming step S30 is performed.

In the third thin film layer forming step S30, a process in which the cycle of forming the second monoatomic layer is repeatedly performed to form the third thin film layer 40 composed of the plurality of second monoatomic layers is performed.

The third thin film layer forming step S30 may include a second-first precursor adsorption step S31, a second inert gas supply step S32, a second-second reactant adsorption and substitution step S33, and a second cycle repetition step S34.

In the second-first precursor adsorption step S31, a process in which the second-first precursor is supplied to the top of the second thin film layer 30 composed of the plurality of first monoatomic layers, i.e., to a surface of the second thin film layer 30, to adsorb the second-first precursor on the top of the second thin film layer 30, i.e., on the surface of the second thin film layer 30, thereby forming a second-first precursor adsorption layer is performed. In this case, the second-first precursor adsorption layer is configured as only a single layer by a self-limiting reaction.

After the second-first precursor adsorption step S31 is completed, the second inert gas supply step S32 is performed.

In the second inert gas supply step S32, a process in which an inert gas is supplied to remove excess second-first precursor from the second-first precursor adsorption layer is performed. In this case, the inert gas removes the excess second-first precursor remaining in the second-first precursor adsorption layer configured as only a single layer by the self-limiting reaction.

After the second inert gas supply step S32 is completed, the second-second reactant adsorption and substitution step S33 is performed.

In the second-second reactant adsorption and substitution step S33, a process in which the second-second reactant is supplied to a top of the second-first precursor adsorption layer, i.e., to a surface of the second-first precursor adsorption layer, to adsorb the second-second reactant on the top of the second-first precursor adsorption layer, i.e., on the surface of the second-first precursor adsorption layer, thereby forming the second monoatomic layer through chemical substitution of the second-first precursor adsorption layer with the second-second reactant is performed.

The second-second reactant and the second-first precursor have different components.

Since the second monoatomic layer is formed through chemical substitution of the second-first precursor adsorption layer composed of the second-first precursor with the second-second reactant, the second monoatomic layer has a component different from those of the second-first precursor and the second-second reactant.

In the process of forming the second monoatomic layer through chemical substitution, a remaining component among the components of the second-first precursor and the second-second reactant is discharged as gas.

After the second-second reactant adsorption and substitution step S33 is completed, the second cycle repetition step S34 is performed.

In the second cycle repetition step S34, a process in which a cycle of sequentially performing the second-first precursor adsorption step S31, the second inert gas supply step S32, and the second-second reactant adsorption and substitution step S33 is repeated to form the plurality of second monoatomic layers, thereby forming the third thin film layer 40 composed of the plurality of second monoatomic layers is performed.

Through the second cycle repetition step S34, the third thin film layer 40 composed of the plurality of second monoatomic layers may be formed to a predetermined thickness.

In other words, the second cycle repetition step S34 is performed until the third thin film layer 40 composed of the plurality of second monoatomic layers is formed to a predetermined thickness, and the thickness of the third thin film layer 40 is preferably in the range of equal to or greater than 20 nm to equal to or less than 3 μm.

After the third thin film layer forming step S30 is completed through the second-first precursor adsorption step S31, the second inert gas supply step S32, the second-second reactant adsorption and substitution step S33, and the second cycle repetition step S34 is completed, the formation of the thin film layer of the metal part 1 for the process chamber according to the exemplary embodiment of the present invention is completed.

Each of the second monoatomic layers, i.e., the third thin film layer 40, has a component different from that of each of the first monoatomic layers 31, i.e., the second thin film layer 30.

For example, when the component of each of the second monoatomic layers, i.e., the third thin film layer 40, is aluminum oxide (Al₂O₃), the component of each of the first monoatomic layers 31, i.e., the second thin film layer 30, is silicon dioxide (SiO₂).

As above, as the second thin film layer 30 and the third thin film layer 40 have different components, the first-first and second-first precursors have different components, or the second-first and second-second reactants have different components.

For example, even if the first-first precursor and the second-first precursor have the same components, the second-first reactant and the second-second reactant have different components, so that the second thin film layer 30 composed of the plurality of first monoatomic layers 31 and the third thin film layer 40 composed of the plurality of second monoatomic layers may have different components. In other words, at least one pair of the first-first and second-first precursors and the second-first and second-second reactants are required to have different components.

The metal part 1 for the process chamber according to the exemplary embodiment of the present invention having the above-described configuration has the following effects.

By forming the first thin film layer 20 composed of the anodic oxide film layer on the top of the metal base 10, even if the second thin film layer 30 and/or the third thin film layer 40 is removed, it is possible to prevent a foreign substance of the metal base 10 from being easily eluted. This is because the first thin film layer 20 composed of the anodic oxide film layer is formed by anodizing the metal base 10 so that the anodic oxide film layer grows on the surface of the metal base 10, with the result that the anodic oxide film layer has a high bonding property with the metal base 10, so that the foreign substance of the metal base 10 cannot be easily eluted.

By forming the first thin film layer 20 composed of the anodic oxide film layer on the top of the metal base 10 and forming the second thin film layer 30 composed of the plurality of first monoatomic layers on the top of the first thin film layer 20, it is possible to secure a sufficient thickness of the thin film layer and to prevent outgassing.

First, in terms of securing the thickness of the thin film layer, when a monoatomic layer is formed directly on the top of the metal base 10, a plurality of monoatomic layers is required to be formed, which requires a lot of time. Therefore, by forming the first thin film layer 20 composed of the anodic oxide film layer on the top of the metal base 10 and then forming the second thin film layer 30 on the top of the first thin film layer 20, it is possible to more effectively secure the thickness of the thin film layer.

In addition, even when the first thin film layer 20 is composed of only the non-porous bather layer 21, the second thin film layer 30 or the second thin film layer 30 and the third thin film layer 40 compensate for a small thickness of the non-porous bather layer 21, thereby solving the problem of the related art due to a small thickness of a non-porous bather layer.

In detail, in the case of the related art, when a thin film layer of a metal part for a process chamber is composed of only a non-porous bather layer, the thin film layer has a very small thickness, causing cracks and plasma arcing to occur.

However, in the case of the present invention, even if the first thin film layer 20 is composed of only the non-porous bather layer 21, the second thin film layer 30 can compensate for an insufficient thickness, so that the above problem of the related art can be solved.

In terms of preventing outgassing, in the case of the related art, when the thin film layer of the metal part for the process chamber is composed of the non-porous bather layer and a porous layer, outgassing occurs due to pores of the porous layer.

However, in the case of the present invention, the second thin film layer 30 composed of the plurality of first monoatomic layers 31 covers the pores 23a of the porous layer 23 of the first thin film layer 20, thereby preventing outgassing from occurring.

Since the second thin film layer 30 is composed of the plurality of first monoatomic layers 31, there is a great advantage in covering the pores 23a.

FIG. 4A illustrates a porous layer 23′ of a metal part for a process chamber according to the related art, and a pore 23a′ inside the porous layer 23′.

When a deposition process is performed with a chemical vapor deposition apparatus or a physical vapor deposition apparatus, as illustrated in FIG. 4B, one deposition layer 31′ is formed on a top of the porous layer 23′.

In this case, the relationship between a thickness T1′ of a top portion of the deposition layer 31′ formed on a top surface of the porous layer 23′, a thickness T2′ of the deposition layer 31′ formed on a bottom surface of the pore 23a′, and a thickness T3′ of the deposition layer 31′ formed on an inner wall of the pore 23a′ satisfies “(T1′>T2′>T3′)”.

As illustrated in FIG. 4C, when a second thin film layer 30′ is formed by increasing the thickness of the deposition layer 31′, a space 23b′ is formed inside the second thin film layer 30′.

When the metal part for the process chamber according to the related art is used as a part of the process chamber or as a metal part, when a top surface of the second thin film layer 30′ is removed due to a chemical reaction with process gas due to long-term use, the space 23b′ is exposed to the outside. Therefore, a foreign substance may remain in the space 23b′, causing the above-described outgassing problem.

However, in the case of the present invention, since the second thin film layer 30 is composed of the plurality of first monoatomic layers 31, the above problem can be solved.

In detail, in the state of FIG. 5A in which the pore 23a is formed in the porous layer 23, when one first monoatomic layer 31 is formed through chemical substitution of the first-first precursor with the first-second reactant, the state as illustrated in FIG. 5B is obtained.

In this case, the relationship between a thickness T1′ of a top portion of the first monoatomic layer 31 formed on a top surface of the porous layer 23, a thickness T2′ of the first monoatomic layer 31 formed on a bottom surface of the pore 23a, and a thickness T3′ of the first monoatomic layer 31 formed on an inner wall of the pore 23a satisfies “(T T3′)”. In other words, the first monoatomic layer 31 is formed on the porous layer 23, i.e., the first thin film layer 20, with a uniform thickness.

When such a cycle is repeated to form the plurality of first monoatomic layers 31 to form the second thin film layer 30, as illustrated in FIG. 5C, no space exists inside the second thin film layer 30, and the pore 23a is entirely filled with the second thin film layer 30. In other words, a part of the second thin film layer 30, i.e., a part of the lower portion of the second thin film layer 30, is located inside the pore 23a of the porous layer 22 of the first thin film layer 20, so that the pore 23a is entirely filled with the second thin film layer 30. Therefore, it is possible for the metal part 1 for the process chamber according to the present invention completely solve the problem of outgassing.

By configuring the second thin film layer 30 and the third thin film layer 40 to have different components, it is possible to manufacture the metal part 1 for the process chamber that has various properties.

For example, when the second thin film layer 30 is composed of a component having a heat resistance property and the third thin film layer 40 is composed of a component having a corrosion resistance property, the metal part 1 for the process chamber is capable of simultaneously having high heat resistance and corrosion resistance properties.

In addition, when the second thin film layer 30 is composed of a component having a breakdown voltage property and the third thin film layer 40 is composed of a component having a plasma resistance property, the metal part 1 for the process chamber is capable of simultaneously having high breakdown voltage and plasma resistance properties.

The metal part 1 for the process chamber according to the exemplary embodiment of the present invention may be implemented in all kinds of forms, including: i) a form in which the first thin film layer 20 composed of only the non-porous bather layer 21 is on the top of the metal base and the second thin film layer 30 is on the top of the first thin film layer 20; ii) a form in which the first thin film layer 20 composed of the non-porous bather layer 21 and the porous layer 23 is on the top of the metal base 10 and the second thin film layer 30 is on the first thin film layer 20; iii) a form in which the first thin film layer 20 composed of only the non-porous bather layer 21 is on the top of the metal base 10, the second thin film layer 30 is on the top of the first thin film layer 20, and the second thin film layer 30 is on the third thin film layer 40; and iv) a form in which the first thin film layer 20 composed of the non-porous bather layer 21 and the porous layer 23 is on the top of the metal base 10, the second thin film layer 30 is on the first thin film layer 20, and the third thin film layer 40 is on the top of the second thin film layer 30.

The metal part 1 for the process chamber according to the exemplary embodiment of the present invention may further include a plurality of monoatomic thin film layers each of which is composed of a monoatomic layer on a top of the third thin film layer 40.

For example, the metal part 1 for the process chamber according to the exemplary embodiment of the present invention described above may further include a fourth thin film layer (not illustrated) formed on the top of the third thin film layer 40, a fifth thin film layer formed on a top of the fourth third thin film layer, and a sixth thin film layer formed on a top of the fifth thin film layer. In this case, the configuration and the method of forming the plurality of monoatomic thin film layers (i.e., the fourth to sixth thin film layers) remain the same as those of the third thin film layer 40 described above, and thus descriptions thereof will be omitted. Here, the number of the monoatomic thin film layers is not limited.

Each of the plurality of monoatomic thin film layers has a component different from those of the second thin film layer 30 and the third thin film layer 40.

In other words, the plurality of monoatomic thin film layers, the second thin film layer 30, and the third thin film layer 40 preferably have different components, so that different properties are imparted to the metal part 1 for the process chamber.

The second thin film layer 30 may be composed of one layer, i.e., a single first monoatomic layer 31, rather than the plurality of first monoatomic layers, and the third thin film layer 40 may also be composed of one layer, i.e., a single second monoatomic layer, rather than the plurality of second monoatomic layers.

In addition, each of the plurality of monoatomic thin film layers (i.e., the fourth to sixth thin film layers) may also be composed of a plurality of monoatomic layers, or a single monoatomic layer. Here, the number of the monoatomic thin film layers is not limited.

Therefore, each of the second thin film layer 30, the third thin film layer 40, and the plurality of monoatomic thin film layers (i.e., the fourth to sixth thin film layers) may be selectively composed of a single monoatomic layer or a plurality of monoatomic layers.

For example, the second thin film layer 30 may be composed of the plurality of first monoatomic layers 31, the third thin film layer 40 may be composed of a single second monoatomic layer, the fourth thin film layer may be composed of a single third monoatomic layer, the fifth thin film layer may be composed of a single fourth monoatomic layer, and the sixth thin film layer may be composed of a single fifth monoatomic layer. On the other hand, the second thin film layer 30 may be composed of the plurality of first monoatomic layers 31, the third thin film layer 40 may be composed of the plurality of second monoatomic layers, the fourth thin film layer may be composed of a single third monoatomic layer, the fifth thin film layer may be composed of a single fourth monoatomic layer, and the sixth thin film layer may be composed of a plurality of fifth monoatomic layers.

In other words, the metal part 1 for the process chamber according to the exemplary embodiment of the present invention may be implemented in all kinds of forms, including: v) a form in which the first thin film layer 20 composed of only the non-porous bather layer 21 is on the top of the metal base 10, and a plurality of monoatomic thin film layers is formed on the top of the first thin film layer 20, each of the plurality of monoatomic thin film layers being composed of a single monoatomic layer; vi) a form in which the first thin film layer 20 composed of only the non-porous bather layer 21 is on the top of the metal base 10, and a plurality of monoatomic thin film layers is formed on the top of the first thin film layer 20, each of the plurality of monoatomic thin film layers being composed of a plurality of monoatomic layers; and vii) a form in which the first thin film layer 20 composed of only the non-porous bather layer 21 is on the top of the metal base 10, and a plurality of monoatomic thin film layers is formed on the top of the first thin film layer 20, each of the plurality of monoatomic thin film layers being selectively composed of a single monoatomic layer or a plurality of monoatomic layers.

As above, by allowing each of the second thin film layer 30, the third thin film layer 40, and the plurality of monoatomic thin film layers (i.e., the fourth to sixth thin film layers) to be selectively composed of a single or a plurality of monoatomic layers, there is an advantage in that the thin film layer of the metal part 1 for the process chamber can be easily formed to a desired thickness.

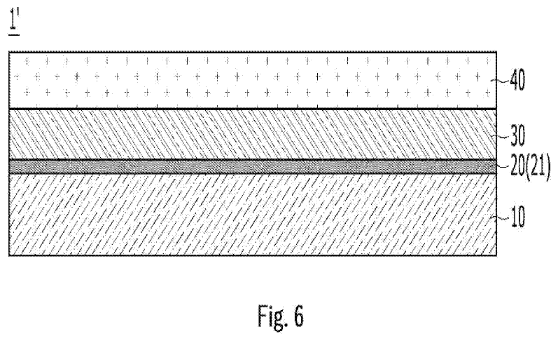

In the case of the above-described i) the form in which the first thin film layer 20 composed of only the non-porous bather layer 21 is on the metal base 10 and the second thin film layer 30 is on the first thin film layer 20, this is illustrated in FIG. 6 as a modified example.

FIG. 6 is a view illustrating a metal part for a process chamber according to a modified example of the present invention.

As illustrated in FIG. 6, the metal part 1′ for the process chamber according to the modified example of the present invention may include a first thin film layer 20 composed of only a non-porous bather layer 21 on a top of a metal base 10, a second thin film layer 30 composed of a plurality of monoatomic layers on a top of the first thin film layer 20, and a third thin film layer composed of a plurality of monoatomic layers on a top of the second thin film layer 30.

In the metal part 1′ for the process chamber according to the modified example of the present invention, each of the second thin film layer 30 and the third thin film layer 40 may be composed of a single monoatomic layer, and the provision of the third thin film layer 40 may be omitted. In addition, a plurality of monoatomic thin film layers may be formed on a top of the third thin film layer 40.

In the metal part 1′ for the process chamber according to the modified example of the present invention as described above, no pores 23a illustrated FIG. 1 exist, the problem of outgassing may be fundamentally solved.

In addition, since the second thin film layer 30 is formed on the top of the first thin film layer 20, even if the first thin film layer 20 cracks, a foreign substance of the metal base 10 may be effectively prevented from eluting to the outside.

In detail, when the first thin film layer 20 is formed by anodizing the metal base 10 to form an anodic oxide film composed of only the non-porous bather layer 21, the first thin film layer 20 (the anode oxide film layer or non-porous bather layer 21) may be formed to have a relatively small thickness (several hundreds of nm) as described above.

If only the first thin film layer 20 is formed on the metal base 10 and the metal base 10 is made of an alloy, the foreign substance inside the alloy metal base 10 is eluted to the outside, causing cracks in the thin first thin film layer 20. Therefore, the foreign substance may be eluted to the outside through the first thin film layer 20 and becomes a major cause of contamination in the process chamber. In this case, the foreign substance may be an additive component added to the alloy metal base 10. The additive component refers to various elements (Mn, Si, Mg, Cu, Zn, Cr, etc.) added when preparing the alloy.

However, as above, when the second thin film layer 30 composed of the monoatomic layer is formed on the top of the first thin film layer 20, the second thin film layer 30 can compensate for the relatively small thickness of the first thin film layer 20, thereby preventing cracks in the first thin film layer 20. Therefore, the foreign substance inside the alloy metal base 10 may be prevented from eluting to the outside of the metal parts 1 and 1′ for the process chambers, thereby preventing contamination of the process chamber.

In particular, when the second thin film layer 30 is composed of the plurality of monoatomic layers, this enables the thickness of the second thin film layer 30 to increase, thereby more effectively preventing elution of the foreign substance. In addition, when the third thin film layer 40 is formed on the top of the second thin film layer 30, this enables the thickness of thin film layers formed on the top of the metal base 10 to more increase, thereby more effectively preventing elution of the foreign substance.

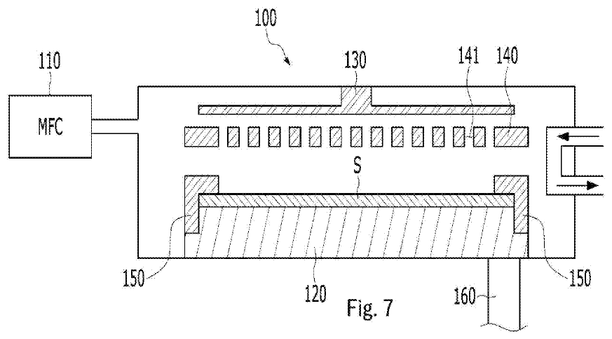

Hereinafter, with reference to FIG. 7, a description will be given of a process chamber 100 for chemical vapor deposition in which the metal part 1 for the process chamber according to the exemplary embodiment of the present invention constitutes a part of the process chamber or is installed as a metal part.

FIG. 7 is a view illustrating the process chamber for chemical vapor deposition in which chemical vapor deposition is performed, in which the metal part according to the exemplary embodiment of the present invention constitutes an inner surface of the process chamber or is installed as a metal part.

The metal part 1 for the process chamber according to the exemplary embodiment of the present invention may constitute the inner surface of the process chamber 100 for chemical vapor deposition or may be installed as a metal part.

The process chamber 100 for chemical vapor deposition may include a mass flow controller (MFC) 110 provided outside the process chamber 100 for chemical vapor deposition, a susceptor 120 installed inside the process chamber 100 for chemical vapor deposition to support a substrate S, a backing plate 130 disposed at an inner top portion of the process chamber 100 for chemical vapor deposition, a diffuser 140 disposed below the backing plate 130 to supply process gas to the substrate S, a shadow frame 150 disposed between the susceptor 120 and the diffuser 140 to cover an edge of the substrate S, a process gas exhaust part 160 for allowing exhaust of the process gas supplied from a process gas supply part (not illustrated), a guard ring (not illustrated) installed in each of the process gas supply part and the process gas exhaust part, and a slit valve (not illustrated) installed in each of the process gas supply part and the process gas exhaust part.

The configurations and functions of the MFC 110, the susceptor 120, the backing plate 130, the diffuser 140, the shadow frame 150, the process gas supply part, the process gas exhaust part 160, the guard ring, and the slit valve of the process chamber 100 for chemical vapor deposition are the same as those of a process chamber for chemical vapor deposition according to the related art, and thus detailed descriptions thereof will be omitted.

At least one of the inner surface of the process chamber 100 for chemical vapor deposition, the susceptor 120, the backing plate 130, the diffuser 140, the shadow frame 150, the guard ring, and the slit valve may function as the metal part 1 for the process chamber.

The process chamber 100 for chemical vapor deposition performs chemical vapor deposition on the substrate S in such a manner that the process gas supplied from the process gas supply part is introduced into the backing plate 130 and then is sprayed toward the substrate S through through-holes 141 of the diffuser 140. The process gas is a plasma gas which is highly corrosive and erosive, and the inner surface of the process chamber 100 for chemical vapor deposition and the susceptor 120, the backing plate 130, the diffuser 140, the shadow frame 150, the process gas exhaust part 160, the guard ring, and the slit valve (hereinafter referred to as “metal parts”) installed inside the process chamber 100 for chemical vapor deposition come into contact with the process gas.

Since the metal part 1 for the process chamber is composed of the first thin film layer 20 and the second thin film layer 30 or the first thin film layer 20 to the third thin film layer 40, while improving heat resistance, corrosion resistance, breakdown voltage, and plasma resistance properties, the problem of the related art of outgassing and particle generation caused by the pores 23a is solved. In addition, the yield of a finished product manufactured by the process chamber 100 for chemical vapor deposition is improved, the process efficiency of the process chamber 100 for chemical vapor deposition is improved, and the maintenance cycle of the process chamber 100 for chemical vapor deposition is prolonged.

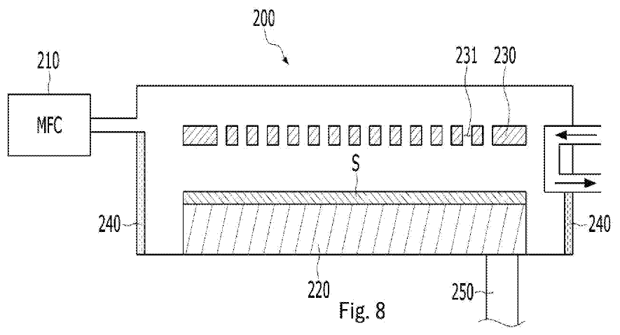

Hereinafter, with reference to FIG. 8, a process chamber 200 for dry etching in which the metal part 1 for the process chamber according to the exemplary embodiment of the present invention constitutes an inner surface of the process chamber or is installed as a metal part will be described.

FIG. 8 is a view illustrating a process chamber for dry etching in which dry etching is performed, in which the metal part according to the exemplary embodiment of the present invention constitutes the inner surface of the process chamber or is installed as a metal part.

As illustrated in FIG. 8, the process chamber 200 for dry etching includes a mass flow controller (MFC) 210 provided outside the process chamber 200 for dry etching, a bottom electrode 220 installed inside the process chamber 200 for dry etching to support a substrate S, an upper electrode 230 disposed above the bottom electrode 220 to supply process gas to the substrate S, a wall liner 240 installed on an inner wall of the process chamber 200 for dry etching, a process gas exhaust part 250 for allowing exhaust of the process gas supplied from a process gas supply part (not illustrated), a guard ring (not illustrated) installed in each of the process gas supply part and the process gas exhaust part, and a slit valve (not illustrated) installed in each of the process gas supply part and the process gas exhaust part.

The configurations and functions of the MFC 210, the bottom electrode 220, the upper electrode 230, the wall liner 240, the process gas supply part, the process gas exhaust part 250, the guard ring, and the slit valve of the process chamber 200 for dry etching are the same as those of a process chamber for dry etching according to the related art, and thus detailed descriptions thereof will be omitted.

However, the bottom electrode 220 may include an electrostatic chuck (ESC, not illustrated) that minimizes generation of static electricity on the substrate S, and a baffle (not illustrated) that maintains a constant flow of process gas around the substrate S, so that uniform etching may occur on the substrate S.

At least one of the inner surface of the process chamber 200 for dry etching, the bottom electrode 220, the electrostatic chuck of the bottom electrode 220, the baffle of the bottom electrode 220, the upper electrode 230, the wall liner 240, the process gas exhaust part 250, the guard ring, and the slit valve may function as the metal part 1 for the process chamber.

The process chamber 200 for dry etching performs dry etching on the substrate S in such a manner that the process gas supplied from the process gas supply part is introduced into the upper electrode 230 and then is sprayed toward the substrate S through through-holes 231 of the upper electrode 230. The process gas is a plasma gas which is highly corrosive and erosive, and the inner surface of the process chamber 200 for dry etching and the bottom electrode 220, the electrostatic chuck of the bottom electrode 220, the baffle of the bottom electrode 220, the upper electrode 230, the wall liner 240, the process gas exhaust part 250, the guard ring, and the slit valve (hereinafter referred to as “metal parts”) installed inside the process chamber 200 for dry etching come into contact with the process gas.

Since the metal part 1 for the process chamber is composed of the first thin film layer 20 and the second thin film layer 30 or the first thin film layer 20 to the third thin film layer 40, while improving heat resistance, corrosion resistance, breakdown voltage, and plasma resistance properties, the problem of the related art of outgassing and particle generation caused by the pores 23a is solved. In addition, the yield of a finished product manufactured by the process chamber 200 for dry etching is improved, the process efficiency of the process chamber 200 for dry etching is improved, and the maintenance cycle of the process chamber 200 for dry etching is prolonged.

Although the exemplary embodiments of the present invention have been described for illustrative purposes, those skilled in the art will appreciate that various modifications, additions and substitutions are possible, without departing from the scope and spirit of the invention as disclosed in the accompanying claims.

What is claimed is:

1. A method of forming a thin film layer of a metal part for a process chamber, the method comprising:
anodizing a metal base to form a first thin film layer composed of an anodic oxide film layer on a top surface of the metal base, wherein the anodic oxide film layer only composed of a non-porous bather layer having no pores therein, and the non-porous bather layer is formed by anodizing the metal base;
adsorbing a first-first precursor on a top of the first thin film layer;
supplying a first-second reactant of a different kind from the first-first precursor to form a first monoatomic layer through chemical substitution of the first-second reactant with the first-first precursor; and
repeatedly performing a cycle of forming the first monoatomic layer to form a second thin film layer composed of a plurality of first monoatomic layers on the top of the first thin film layer.

2. The method of claim 1, wherein a thickness of the non-porous bather layer is in a range of equal to or greater than 100 nm to equal to or less than 1 μm.

3. The method of claim 1, wherein the cycle is repeatedly performed until a thickness of the second thin film layer becomes in a range of equal to or greater than 20 nm to equal to or less than 3 μm.

4. The method of claim 1, further comprising:
forming a third thin film layer composed of a plurality of second monoatomic layers on the top of the second thin film layer by adsorbing a second-first precursor on a top of the second thin film layer, by supplying a second-second reactant of a different kind from the second-first precursor to form a second monoatomic layer through chemical substitution of the second-second reactant with the second-first precursor, and by repeatedly performing a cycle of forming the second monoatomic layer,
wherein the second thin film layer and the third thin film layer have different components.

5. The method of claim 1, wherein the metal base is a metal part that is installed inside the process chamber in which chemical vapor deposition is performed, and is at least one of a diffuser, a backing plate, a shadow frame, a susceptor, a guard ring, and a slit valve.

6. The method of claim 1, wherein the metal base is a metal part that is installed inside the process chamber in which dry etching is performed, and is at least one of a bottom electrode, an electrostatic chuck of the bottom electrode, a baffle of the bottom electrode, an upper electrode, a wall liner, a guard ring, and a slit valve.
